(19) United States
(12) Patent Application Publication
(10) Pub. No.: US 2006/0044040 A1
(43) Pub. Date: Mar. 2, 2006

(54) VARIABLE ATTENUATION CIRCUIT

(75) Inventor: Kazuo Kawai, Tokyo (JP)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(73) Assignee: GENERAL RESEARCH OF ELECTRONICS, INC., Tokyo (JP)

(21) Appl. No.: 10/905,240

(22) Filed: Dec. 22, 2004

(30) Foreign Application Priority Data
Aug. 24, 2004 (JP) 2004-243683

(51) Int. Cl. H03L 5/00

(52) U.S. Cl. 327/308

(57) ABSTRACT

A variable attenuation circuit comprises a common-base connected transistor, a collector load resistor connected between a collector of the transistor and an AC ground point and having a small resistance value of a few ohms or so, and a bias adjustment resistor connected to the base of the transistor, for adjusting a degree of signal attenuation. An input signal is supplied to an emitter of the transistor and an attenuated output signal is derived from the collector of the transistor.

### FIELD OF THE INVENTION

The present invention relates to a variable attenuation circuit using a common-base connected transistor, and particularly to a variable attenuation circuit wherein a collector load resistance value of a common-base connected transistor is substantially set lower than a normally used resistance value to obtain a signal attenuation characteristic.

### DESCRIPTION OF THE RELATED ART

As a variable attenuation circuit usable up to a high frequency signal region, one using semiconductor elements, particularly, one in which PIN diodes are used as semiconductor elements, has heretofore been put into practical use. A variable attenuation circuit configured using one PIN diode encounters difficulties in greatly changing a signal attenuation quantity or signal attenuation. Therefore, PIN diodes of three or so are normally used and combined to thereby relatively extend a range of a change in signal attenuation. Incidentally, one example illustrative of this type of variable attenuation circuit has been disclosed in the Revised High-Frequency Circuit Setting Know-How, 6, 1 [8] Electronic Attenuator, p. 219, CQ Publishing Co., Ltd., 1992 (non-patent document 1).

If a signal frequency region intended for attenuation is a range of kilohertz (KHz) or about a few tens of megahertz (MHz) higher than it, then such a variable attenuation circuit is capable of obtaining signal attenuation characteristics satisfactory for all signal frequency regions intended for attenuation by selecting its corresponding PIN diodes applicable to the signal frequency region intended for attenuation. Consequently, about 60 dB or a value greater than it can be achieved as the maximum value of a signal attenuation quantity.

When, however, the upper limit frequency of the signal frequency region intended for attenuation becomes much higher, particularly when the signal frequency region intended for attenuation reaches 100 megahertz (MHz) or so or a frequency higher than it, the signal attenuation is sequentially decreased with an increase in signal frequency even though a PIN diode satisfactory in high frequency characteristic is selected and used. Even in the case of a variable attenuation circuit having a circuit construction identical to above, the maximum value of its signal attenuation quantity is reduced to about 60 dB referred to above or from a value higher than it to a value ranging from about 20 to 30 dB when the upper limit frequency of the signal frequency region intended for attenuation reaches about 1 gigahertz (GHz).

It has been found that the reason why when the upper limit frequency of the signal frequency region intended for attenuation becomes high, the signal attenuation quantity is reduced, results from the fact that this type of known variable attenuation circuit principally depends on the structure of the PIN diode per se. That is, this is because since impedances such as a junction capacitance of ajunction of the PIN diode, a parasitic capacitance of a lead wire for the PIN diode, etc. are brought to innegligible magnitude as compared with an internal resistance thereof when the upper limit frequency of the signal frequency region intended for attenuation goes high, these impedances serve so as to cancel out a change in the internal resistance thereof even though the internal resistance of the PIN diode is changed.

For these reasons, there is a need to further increase the number of PIN diodes to be used and take a means for more strictly preventing electromagnetic coupling and electrostatic coupling formed between input and output circuits of a variable attenuation circuit capable of increasing the maximum value of a signal attenuation quantity where such a variable attenuation circuit is obtained, even though the upper limit frequency of the signal frequency region intended for attenuation is high. Consequently, the variable attenuation circuit becomes complex in circuit construction and increases in circuit scale. As a result, the variable attenuation circuit had no other choice but to become expensive in manufacturing cost.

### SUMMARY OF THE INVENTION

The present invention has been made in view of the foregoing. An object of the present invention is to provide a variable attenuation circuit which avoids complexity of a circuit construction thereof and is capable of increasing the maximum value of a signal attenuation quantity even though the upper limit frequency of a signal frequency region intended for attenuation is a few gigahertz (GHz) or so.

As mentioned above, the factor that the maximum value of the signal attenuation quantity is lowered where the upper limit frequency of the signal frequency region intended for attenuation becomes high, depends on the structure of the PIN diode per se. Therefore, the variable attenuation circuit using the PIN diode encounters difficulties in avoiding a reduction in the maximum value of the signal attenuation quantity so long as the PIN diode is used.

Thus, the present invention has paid attention to the fact that a normal junction bipolar transistor is used as an alternative to the use of the PIN diode in the variable attenuation circuit, and the bipolar transistor may be used in a common-base connection configuration. That is, when the bipolar transistor is connected in the common base mode, a junction capacitance (normally also called “feedback capacitance”) between its collector and base (between C-B) and a diffusion capacitance between its base and emitter (between B-E) exist as well known. Further, a junction capacitance between its collector and emitter also exists. Since, however, the base connected to ground exists in an intermediate part between the collector and emitter, there is little need to take into consideration the junction capacitance between the collector and emitter as in the PIN diode.

Thus, when the common-base connected transistor is used in the variable attenuation circuit, a signal intended for attenuation is applied between the emitter and base thereof and the corresponding signal may be taken out from between the collector and base thereof. At this time, the junction capacitance between the collector and base of the transistor increases an electrostatic capacitance between an output line and a reference potential point (earth point), whereas the diffusion capacitance between the emitter and base of the transistor increases an electrostatic capacitance between an input line and the reference potential point (earth). Therefore, the increased electrostatic capacitances referred to above serve so as to degrade a high-frequency cutoff characteristic which restricts a frequency band at the upper limit frequency of the signal frequency region intended for attenuation. Thus, in order to provide such a circuit as not to suffer such degradation of high-frequency cutoff characteristic, the present invention is constructed so as to hold the input/output impedances of the common-base connected transistor as low as possible and to be unaffected by the increased electrostatic capacitances.

In general, the common-base connected transistor amplifies the signal inputted to the emitter thereof and fetches the amplified signal from the collector thereof. However, when a resistance value extremely lower than the value of a normally used load resistor, in this case, an extremely low load resistance of a few ohms or so is used as the value of a collector load resistor of the transistor, the signal gain or amplification of the transistor comes to nought due to the extremely low load resistance, instead, a degree of signal attenuation is obtained, so that the transistor operates as a signal attenuator. If the transistor is set to a base bias voltage adjustable configuration to change its base bias voltage in this case, then such a variable attenuation circuit that the operating point of the transistor changes and the maximum value of a signal attenuation quantity changes, can be obtained.

In this case, the input impedance of the common-base connected transistor is extremely low and equivalent to an impedance of a few ohms or so. Therefore, in order to reduce an insertion loss of the transistor as small as possible, there is a need to drive the transistor by a drive circuit having a low possible output impedance, if possible, an ultra-low output impedance of less than or equal to 1 ohm or so. It is preferable to use the drive circuit having such an ultra-low output impedance in that the influence of the increased electrostatic capacitances of the transistor can be avoided and the upper limit frequency of the signal frequency region can be made high.

Thus, in order to attain the above-described object, a variable attenuation circuit according to the present invention comprises a common-base connected transistor, a collector load resistor connected between a collector of the transistor and an AC ground point, which has a small resistance value of a few ohms or so, and a bias adjustment resistor connected to the base of the transistor, for adjusting a degree of signal attenuation, wherein an input signal is supplied to an emitter of the transistor and an attenuated output signal is derived from the collector of the transistor.

In this case, a drive circuit connected to an input of the variable attenuation circuit having the above construction has an emitter-follower connected pretransistor and is equipped with a first construction means wherein an input signal is supplied to a base of the pretransistor, and a signal obtained at an emitter of the pretransistor is supplied to the emitter of the transistor of the variable attenuation circuit.

In the first construction means, the common-base connected transistor of the variable attenuation circuit and the emitter-follower connected pretransistor of the drive circuit make use of transistors of types complementary to each other. The emitter of the common-base connected transistor and the emitter of the emitter-follower connected pretransistor can be directly connected to each other.

Also a drive circuit connected to the input of the variable attenuation circuit having the above construction includes a filter whose impedance on the side of an input terminal thereof indicates a finite value and whose impedance on the side of an output terminal thereof indicates approximately a zero value. The drive circuit is equipped with a second construction means wherein an input signal is supplied to the input terminal of the filter and a signal derived from the output terminal of the filter is supplied to the emitter of the common-base connected transistor.

According to the present invention, the variable attenuation circuit makes use of a common-base connected transistor satisfactory in high frequency characteristic. The transistor has a collector load resistor of which the resistance value is selected to be a value extremely lower than the resistance value of a normally used collector load resistor, i.e., a low resistance value of a few ohms or so. Assuming that as its one example, the resistance value of the collector load resistor is selected to be 5 ohms and the stray capacitance between the collector of the transistor and an earth point is 3 pF, a cutoff frequency indicative of an equivalent low-frequency pass characteristic of the variable attenuation circuit reaches 1/(2π×5×3×10⁻¹²)=10.6 gigahertz (GHz). Thus, in view of such a cutoff frequency, a variable attenuation circuit capable of using up to a few gigahertz (GHz) or so as an upper limit frequency of a signal frequency region intended for attenuation can be realized in a simple circuit configuration. Consequently, an advantageous effect is brought about in that a variable attenuation circuit having a wide frequency band is obtained at low manufacturing cost.

According to the present invention as well, a drive circuit connected to an input of the variable attenuation circuit has an advantageous effect in that since it has an emitter-follower connected pretransistor, and an input signal is supplied to a base of the pretransistor and a signal obtained at an emitter of the pretransistor is supplied to an emitter of the transistor of the variable attenuation circuit, the input of the emitter of the common-base connected transistor can be driven at sufficiently low output impedance defined by an emitter follower, so that the drive circuit is less affected by increased electrostatic capacitances of the common-base connected transistor and hence an upper limit frequency of a signal frequency region can be made high.

Further, according to the present invention, an advantageous effect is brought about in that since the common-base connected transistor of the variable attenuation circuit and the emitter-follower connected pretransistor of the drive circuit make use of transistors of types complementary to each other, and the emitter of the common-base connected transistor and the emitter of the emitter-follower connected pretransistor are directly connected to each other, the input of the emitter of the common-base connected transistor can be driven at sufficiently low impedance defined by an emitter follower, thus making it possible to less reduce the influence of increased electrostatic capacitances of the common-base connected transistor, enhance an upper limit frequency of a signal frequency region and greatly simplify the construction of a connecting portion of the variable attenuation circuit and the drive circuit.

Furthermore, according to the present invention, a drive circuit connected to the input of the variable attenuation circuit has an advantageous effect in that since it includes a filter whose input impedance indicates R ohm corresponding to a finite value and whose output impedance indicates approximately zero ohm, and an input signal is supplied to an input terminal of the filter and a signal derived from an output terminal of the filter is supplied to the emitter of the common-base connected transistor, the input of the emitter of the common-base connected transistor can be driven at extremely low output impedance of the filter, equivalent to approximately zero ohm, thus making it possible to less reduce the influence of increased electrostatic capacitances of the common-base connected transistor and enhance an upper limit frequency of a signal frequency region.

The above and further objects and novel features of the invention will more fully appear from the following detailed description appended claims and the accompanying drawings.

### BRIEF DESCRIPTION OF THE DRAWINGS

FIG. 1 relates to an embodiment of a variable attenuation circuit according to the present invention and is a circuit diagram showing a fragmentary construction including a drive circuit thereof;

FIG. 2 is a characteristic diagram illustrating one example of a relationship between a signal frequency and a signal attenuation quantity in the variable attenuation circuit shown in FIG. 1;

FIG. 3 relates to another embodiment of a variable attenuation circuit according to the present invention and is a circuit diagram showing a fragmentary construction including a drive circuit thereof; and

FIG. 4 relates to a further embodiment illustrative of variable attenuation circuits according to the present invention and is a circuit diagram showing a fragmentary construction including drive circuits thereof.

### DETAILED DESCRIPTION OF THE PREFERRED EMBODIMENTS

Preferred embodiments of the present invention will hereinafter be explained with reference to the accompanying drawings.

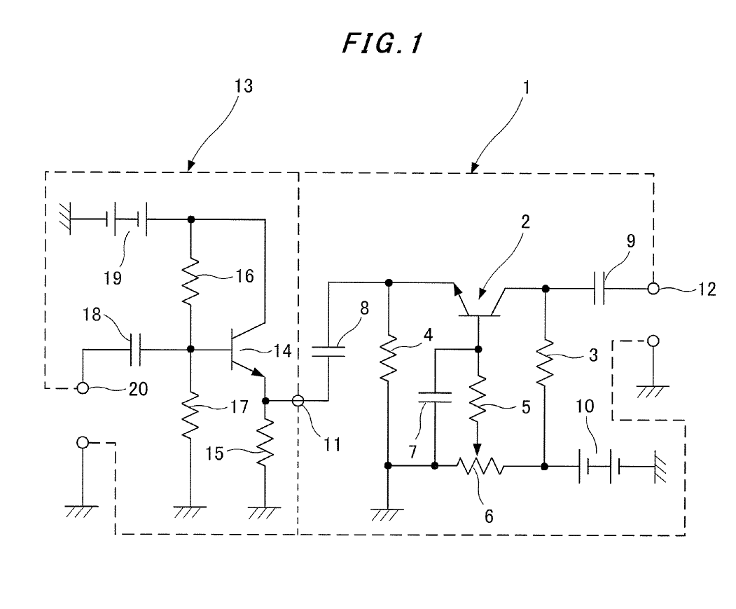

FIG. 1 relates to an embodiment of a variable attenuation circuit according to the present invention and is a circuit diagram showing a fragmentary construction including a drive circuit thereof.

As shown in FIG. 1, the variable attenuation circuit 1 includes a common-base connected transistor 2, a collector load resistor 3, an emitter resistor 4, a base resistor 5, a potentiometer 6 for adjustment of a base bias voltage, a bypass capacitor 7, an input coupling capacitor 8, an output coupling capacitor 9, a first DC power supply 10, a signal coupling terminal 11 and a signal output terminal 12. The drive circuit 13 has an emitter-follower connected transistor 14, an emitter load resistor 15, base bias voltage dividing resistors 16 and 17, an input coupling capacitor 18, a second DC power supply 19 and a signal input terminal 20. The drive circuit 13 shares the signal coupling terminal 11 with the variable attenuation circuit 1.

In the variable attenuation circuit 1, the transistor 2 has a collector connected to a positive electrode of the first DC power supply 10 through the collector load resistor 3 and connected to the signal output terminal 12 through the output coupling capacitor 9, a base connected to an intermediate terminal of the potentiometer 6 through the base resistor 5 and connected to ground through the bypass capacitor 7, and an emitter connected to ground through the emitter resistor 4 and connected to the signal coupling terminal 11 through the input coupling capacitor 8. The potentiometer 6 has one end connected to the positive electrode of the first DC power supply 10 and the other end connected to ground. The first DC power supply 10 has a negative electrode connected to ground. In the drive circuit 13, the transistor 14 has an emitter connected to ground through the emitter load resistor 15 and directly connected to the signal coupling terminal 11, a base connected to the signal input terminal 20 through the input coupling capacitor 18, and a collector connected to a positive electrode of the second DC power supply 19. One 16 of the base bias voltage dividing resistors 16 and 17 is connected between the base and collector of the transistor 14, whereas the other 17 thereof is connected between the base of the transistor 14 and ground. The second DC power supply 19 has a negative electrode connected to ground.

In this case, the collector load resistor 3 of the transistor 2 in the variable attenuation circuit 1 makes use of one having a resistance value extremely lower than the resistance value of the normally used collector load resistor, specifically, a resistance value of a few ohms. The emitter resistor 4 also makes use of one having a resistance value considerably lower than the resistance value of the normally used emitter resistor, e.g., a resistance value ranging from a few ohms to several ten ohms or so. Similarly, the base resistor 5 and the potentiometer 6 also respectively make use of ones having resistance values considerably lower than the resistance value of the normally used base resistor and the resistance value of the normally used potentiometer 6. Since, however, the potentiometer 6 intends to change the operating point of the transistor 2 by its adjustment, each of the base resistor 5 and the potentiometer 6 need to have such a resistance value as to be capable of changing the operating point of the transistor 2 by the adjustment of the potentiometer 6.

The emitter load resistor 15 of the transistor 14 in the drive circuit 13 makes use of one having, as its resistance value, a resistance value lower than that of the normally used emitter load resistor. However, such one as to assume an output impedance value commensurate with an emitter input impedance value of the transistor 2 in the variable attenuation circuit 1 is selected as its resistance value.

The variable attenuation circuit 1 including the drive circuit 13 provided with the construction referred to above is operated as follows:

When a signal is supplied to the signal input terminal 20 in the drive circuit 13, the signal is supplied to the base of the emitter-follower connected transistor 14 through the input coupling capacitor 18. The transistor 14 current-amplifies the signal supplied to the base thereof and derives the amplified signal from the emitter thereof, followed by being supplied to the signal coupling terminal 11. Next, the variable attenuation circuit 1 inputs the signal supplied to the signal coupling terminal 11 to the emitter of the common-base connected transistor 2 via the input coupling capacitor 8. The transistor 2 is supposed to amplify the signal inputted to the emitter and output the amplified signal from the collector. Since, however, the resistance value of the collector load resistor 3 is set extremely lower than that of the normal collector load resistor like a few ohms or so, the signal outputted from the collector is attenuated by the collector load resistor 3 extremely low in resistance value, and hence the attenuated signal is supplied from the collector to the signal output terminal 12 through the output coupling capacitor 9.

In this case, the potentiometer 6 has been connected to the base of the transistor 2 in the variable attenuation circuit 1. The potentiometer 6 is adjusted in this condition to control the base bias voltage of the transistor 2, so that the operating point of the transistor 2 is changed. When the operating point of the transistor 2 is changed, a signal attenuation quantity of the transistor 2, i.e., a signal attenuation quantity of the variable attenuation circuit 1 is changed according to the change in operating point. When the resistance value between the intermediate terminal of the potentiometer 6 and the other end thereof is changed from the maximum resistance value to the minimum resistance value (zero ohm value), the base bias voltage of the transistor 2 changes from the maximum value to the minimum value (zero voltage value), and the signal attenuation quantity of the variable attenuation circuit 1 changes between the adjustable minimum attenuation quantity and maximum attenuation quantity, whereby the variable attenuation circuit 1 is constructed.

Meanwhile, the drive circuit 13 illustrated in FIG. 1 is configured using one emitter-follower connected transistor 14 having a low output impedance characteristic in order to make impedance matching with a low input impedance characteristic of the common-base connected transistor 2 in the variable attenuation circuit 1. When on the contrary it is difficult to make the impedance matching with the low input impedance characteristic of the variable attenuation circuit 1 even depending on the low output impedance characteristic of one emitter-follower connected transistor 14 when the transistor 14 is used, two or three emitter-follower connected transistors each having the same circuit construction are used with being connected in parallel, thereby enabling the low output impedance characteristic of the drive circuit 13 to be brought to a desired impedance value.

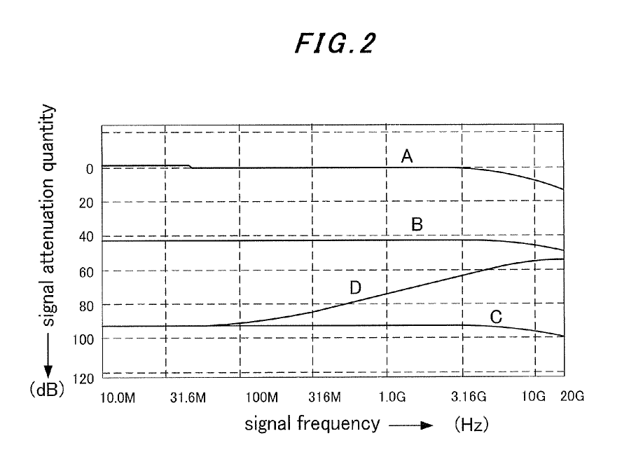

Now, FIG. 2 is a characteristic diagram showing one example of a relationship between a signal frequency and a signal attenuation quantity in the variable attenuation circuit 1 illustrated in FIG. 1. The horizontal axis direction indicates the signal frequency expressed in herz (Hz), whereas the vertical axis direction indicates the signal attenuation quantity expressed in decibel (dB).

In the variable attenuation circuit 1 having obtained such characteristics as shown in FIG. 2, a resistor having a resistance value of 3.3 ohms is used as the collector load resistor 3 of the transistor 2, and a stray capacitance of 3 pF exists between the emitter of the transistor 2 and a reference potential point (earth point) and between the collector thereof and the reference potential point (earth point) respectively. Curves A, B and C shown in the drawing show characteristics obtained where a base current value of the transistor 2 is changed to three types. While the curves A, B and C are all being illustrated as the characteristics obtained when the influence of the coupling capacitance that exists between the emitter and collector of the transistor is eliminated, the characteristic of the curve C results in such a characteristic as expressed in a curve D where a coupling capacitance of 0.01 pF is expected to exist between the emitter and collector upon setting of such a base current as indicated by the curve C.

As shown in FIG. 2, the variable attenuation circuit 1 according to the present embodiment obtains an approximately flat signal attenuation quantity within a signal frequency range of 10 megahertz (MHz) to a few gigahertz (GHz) with respect to each of the curves A, B and C. If a slight reduction in signal attenuation quantity is allowed at a high frequency, then a required signal attenuation quantity is obtained within a signal frequency range up to 10 gigahertz (GHz). Thus, such a simple construction means that one common-base connected transistor 2 is used, makes it possible to obtain a variable attenuation circuit to which signals lying in a wide frequency band intended for attenuation are applicable.

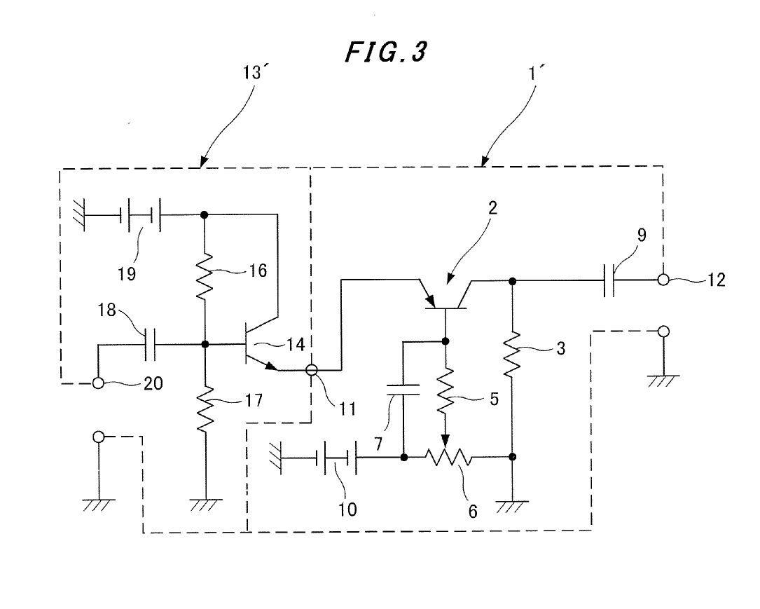

Next, FIG. 3 relates to another embodiment of a variable attenuation circuit according to the present invention and is a circuit diagram showing a fragmentary construction including a drive circuit thereof. FIG. 3 shows a simplified example of an overall circuit construction.

As shown in FIG. 3, the present variable attenuation circuit 1′ is identical to the variable attenuation circuit 1 shown in FIG. 1 in that it has a common-base connected transistor 2, a collector load resistor 3, a base resistor 5, a potentiometer 6 for adjustment of a base bias voltage, a bypass capacitor 7, an output coupling capacitor 9, a first DC power supply 10, a signal coupling terminal 11 and a signal output terminal 12 but different from the variable attenuation circuit 1 in that a conduction type of the transistor 2 is changed to a pnp type (incidentally, the conduction type of the transistor 2 of the variable attenuation circuit 1 is of an npn type), the emitter resistor 4 and the input coupling capacitor 8 are omitted and the first DC power supply 10 is connected between the other end of the potentiometer 6 and a reference potential point (ground point). The present drive circuit 13′ includes an emitter-follower connected transistor 14, base bias voltage dividing resistors 16 and 17, an input coupling capacitor 18, a second DC power supply 19 and a signal input terminal 20. The drive circuit 13′ is identical to the drive circuit 13 illustrated in FIG. 1 in that it shares the signal coupling terminal 11 with the variable attenuation circuit 1 but different from the drive circuit 13 in that no emitter load resistor 15 is provided. That is, in the variable attenuation circuit 1′, the emitter of the transistor 2 is directly connected to the signal coupling terminal 11, and one end of the potentiometer 6 is directly connected to the reference potential point (ground point). In the drive circuit 13′, the emitter of the transistor 14 is directly connected to the signal coupling terminal 11.

Since the variable attenuation circuit 1′ and drive circuit 13′ each having such a construction are almost the same operations as the variable attenuation circuit 1 and drive circuit 13 shown in FIG. 1, the description of the operations of the variable attenuation circuit 1′ and the drive circuit 13′ are omitted. If the variable attenuation circuit 1′ and the drive circuit 13′ are used, then the emitter of the transistor 2 and the emitter of the transistor 14 are directly connected to each other via the signal coupling terminal 11 and any component does not exist therebetween. It is therefore possible to reduce the number of components and simplify a circuit construction as compared with the variable attenuation circuit 1.

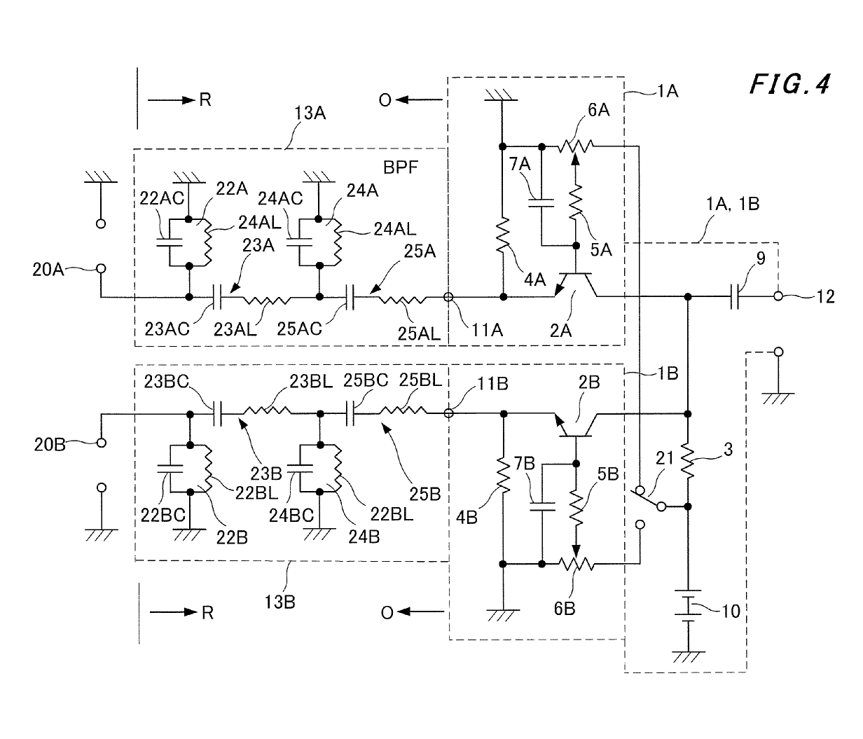

Next, FIG. 4 relates to a further embodiment illustrative of variable attenuation circuits according to the present invention and is circuit diagram showing a fragmentary construction including drive circuits thereof. FIG. 4 shows an example in which the output impedances of the drive circuits are brought into extremely low output impedances and the pairs of the variable attenuation circuits and the drive circuits are placed two in parallel, and either one of the two pairs is used by switching upon its use.

As shown in FIG. 4, a combination of variable attenuation circuits 1A and 1C and a drive circuit 13A constitutes a first pair, whereas a combination of variable attenuation circuits 1B and 1C and a drive circuit 13B constitutes a second pair. A variable attenuation circuit 1C is a circuit portion shared between the first pair and the second pair. The drive circuit 13A of the first pair and the drive circuit 13B of the second pair both comprise bandpass filters different in pass frequency band, which have been designed in such a manner that their input impedance values are respectively R ohm corresponding to a finite value and their output impedance values are respectively zero ohm, that is, bandpass filters (BPF) called “R-0 types”.

The variable attenuation circuit 1A includes a common-base connected transistor 2A, an emitter resistor 4A, a base resistor 5A, a potentiometer 6A for adjustment of a base bias voltage, a bypass capacitor 7A and a signal coupling terminal 11A. The variable attenuation circuit 1B is provided with a common-base connected transistor 2B, an emitter resistor 4B, a base resistor 5B, a potentiometer 6B for adjustment of a base bias voltage, a bypass capacitor 7B and a signal coupling terminal 11B. The variable attenuation circuit 1C is provided with a collector load resistor 3, an output coupling capacitor 9, a first DC power supply 10, a signal output terminal 12 and a selector switch 21.

In the variable attenuation circuit 1A, the transistor 2A has a base connected to an intermediate terminal of the potentiometer 6A through the base resistor 5A and connected to ground through the bypass capacitor 7A together with the other end of the potentiometer 6A, and an emitter connected to ground through the emitter resistor 4A and directly connected to the signal coupling terminal 11A. A collector of the transistor 2A is connected to a positive electrode of the first DC power supply 10 through the collector load resistor 3 of the variable attenuation circuit 1C and connected to the signal output terminal 12 through the output coupling capacitor 9. The potentiometer 6A has one end connected to one switch contact of the selector switch 21 of the variable attenuation circuit 1C.

Similarly, in the variable attenuation circuit 1B, the transistor 2B has a base connected to an intermediate terminal of the potentiometer 6B through the base resistor 5 and connected to ground through the bypass capacitor 7B together with the other end of the potentiometer 6B, and an emitter connected to ground through the emitter resistor 4B and directly connected to the signal coupling terminal 11B. A collector of the transistor 2B is connected to a positive electrode of the first DC power supply 10 through the collector load resistor 3 of the variable attenuation circuit 1C and connected to the signal output terminal 12 through the output coupling capacitor 9. The potentiometer 6B has one end connected to the other switch contact of the selector switch 21 of the variable attenuation circuit 1C.

In the variable attenuation circuit 1C, the first DC power supply 10 has a negative electrode connected to ground, and the selector switch 21 has a movable contact connected to the positive electrode of the first DC power supply 10.

A bandpass filter, which serves as the drive circuit 13A, includes a first LC parallel circuit 22A comprising an inductor 22AL and a capacitor 22AC connected in parallel, a first LC series circuit 23A comprising an inductor 23AL and a capacitor 23AC connected in series, a second LC parallel circuit 24A comprising an inductor 24AL and a capacitor 24AC, and a second LC series circuit 25A comprising an inductor 25AL and a capacitor 25AC connected in series. Similarly, a bandpass filter, which serves as the drive circuit 13B, includes a first LC parallel circuit 22B comprising an inductor 22BL and a capacitor 22BC connected in parallel, a first LC series circuit 23B comprising an inductor 23BL and a capacitor 23BC connected in series, a second LC parallel circuit 24B comprising an inductor 24BL and a capacitor 24BC, and a second LC series circuit 25B comprising an inductor 25BL and a capacitor 25BC connected in series.

In the drive circuit 13A, the first LC parallel circuit 22A has one end connected to its corresponding signal input terminal 20A and the other end connected to a ground point. The first LC series circuit 23A has one end connected to its corresponding signal input terminal 20A and the other end connected to a common connecting point C. The second LC series circuit 25A has one end connected to the common connecting point C and the other end connected to its corresponding signal coupling terminal 11A. The second LC parallel circuit 24A has one end connected to the common connecting point C and the other end connected to the ground point. Similarly, in the drive circuit 13B, the first LC parallel circuit 22B has one end connected to its corresponding signal input terminal 20B and the other end connected to the ground point. The first LC series circuit 23B has one end connected to its corresponding signal input terminal 20B and the other end connected to a common connecting point C. The second LC parallel circuit 24B has one end connected to the common connecting point C and the other end connected to the ground point. The second LC series circuit 25B has one end connected to the common connecting point C and the other end connected to its corresponding signal coupling terminal 11B.

The variable attenuation circuits configured in the above-described manner are operated as follows:

When the movable contact of the selector switch 21 is now switched and connected to one switch contact thereof, a voltage outputted from the first DC power supply 10 is supplied to the collectors of the transistor 2A and the transistor 2B through the collector load resistor 3 and at the same time the output voltage is supplied to the base of the transistor 2A through the switched and connected selector switch 21, so that only the transistor 2A of the variable attenuation circuit 1A is brought into an operating state. When, at this time, a signal is supplied to the signal input terminal 20A of the drive circuit 13A, a signal lying in a first frequency band is extracted from the signal by the bandpass filter constituting the drive circuit 13, which in turn is transmitted and supplied to the variable attenuation circuit 1A through the signal coupling terminal 11A. When the signal is supplied to the emitter of the transistor 2A through the signal coupling terminal 11 in the variable attenuation circuit 1A, the signal outputted from the collector of the transistor 2A is attenuated by the collector load resistor 3 since the collector load resistor 3 has been set to the extremely low resistance value as mentioned above, after which the attenuated signal is supplied to the signal output terminal 12 through the output coupling capacitor 9.

On the other hand, when the movable contact of the selector switch 21 is switched and connected to the other switch contact thereof, the voltage outputted from the first DC power supply 10 is supplied to the collectors of the transistor 2A and the transistor 2B through the collector load resistor 3 as mentioned above. Since, however, the output voltage is supplied to the base of the transistor 2B through the switched and connected selector switch 21, only the transistor 2B of the variable attenuation circuit 1B is brought into an operating state. When a signal is supplied to the signal input terminal 20B of the drive circuit 13B at this time, a signal lying in a second frequency band different from the first frequency band is extracted from the signal by the bandpass filter constituting the drive circuit 13B, after which the extracted signal is transmitted and supplied to the variable attenuation circuit 1B through the signal coupling terminal 11B. When the signal is supplied to the emitter of the transistor 2B through the signal coupling terminal 11B in the variable attenuation circuit 1B, the signal outputted from the collector of the transistor 2B is attenuated by the collector load resistor 3 since the collector load resistor 3 has been set to the extremely low resistance value in like manner, after which the attenuated signal is supplied to the signal output terminal 12 through the output coupling capacitor 9.

According to the present embodiment, the output impedances of the bandpass filter constituting the drive circuit 13A and the bandpass filter constituting the drive circuit 13B are approximately zero ohm, and the input impedances thereof have been set to R ohm corresponding to a finite resistance value. Therefore, the output impedances of the drive circuits 13A and 13B are matched with the extremely low input impedances of the variable attenuation circuits 1A and 1B even without parallel-connecting the two or three circuits identical in circuit configuration to reduce the output impedances of the drive circuits as in the known drive circuits, whereby the constructions of the drive circuits 13A and 13B can be simplified as compared with the known drive circuits.

As described above, the variable attenuation circuit according to the present invention is capable of effectively attenuating signals having frequencies ranging from a high frequency band in a megahertz region to an ultra high frequency band of a few gigahertz (GHz) using the common-base connected single transistor 2, 2A or 2B and the collector load resistor 3 having the extremely low resistance value. A variable attenuation circuit simple in circuit construction can be obtained which can expand a signal frequency band available for the variable attenuation circuit and reduces components to be used, as compared with this type of variable attenuation circuit configured using the PIN diodes.

While the preferred forms of the present invention have been described, it is to be understood that modifications will be apparent to those skilled in the art without departing from the spirit of the invention. The scope of the invention is to be determined solely by the following claims.

What is claimed is:

1. A variable attenuation circuit comprising:
a common-base connected transistor;
a collector load resistor connected between a collector of said transistor and an AC ground point, said collector load resistor having a small resistance value of a few ohms or so; and
a bias adjustment resistor connected to the base of said transistor, for adjusting a degree of signal attenuation,
wherein an input signal is supplied to an emitter of said transistor and an attenuated output signal is derived from the collector of said transistor.

2. The variable attenuation circuit according to claim 1, further including a drive circuit connected to an input of said variable attenuation circuit, said drive circuit having an emitter-follower connected pretransistor, wherein an input signal is supplied to a base of said pretransistor, and a signal obtained at an emitter of the pretransistor is supplied to the emitter of said transistor of said variable attenuation circuit.

3. The variable attenuation circuit according to claim 2, wherein said common-base connected transistor of said variable attenuation circuit and said emitter-follower connected pretransistor of said drive circuit make use of transistors of types complementary to each other, and the emitter of said common-base connected transistor and the emitter of said emitter-follower connected pretransistor are directly connected to each other.

4. The variable attenuation circuit according to claim 1, further comprising a drive circuit connected to the input of said variable attenuation circuit, said drive circuit including a filter whose impedance on the side of an input terminal thereof indicates a finite value and whose impedance on the side of an output terminal thereof indicates approximately a zero value, wherein an input signal is supplied to the input terminal of said filter and a signal derived from the output terminal of said filter is supplied to the emitter of said common-base connected transistor.
